(19) United States
(12) Patent Application Publication
(10) Pub. No.: US 2026/0068700 A1
(43) Pub. Date: Mar. 5, 2026

(54) SEMICONDUCTOR PACKAGE INCLUDING REDISTRIBUTION STRUCTURES

(71) Applicant: Samsung Electronics Co., Ltd., Suwon-si (KR)

(72) Inventors: Taeoh Ha, Suwon-si (KR); Jusuk Kang, Suwon-si (KR); Jongho Park, Suwon-si (KR); Chanwook Park, Suwon-si (KR); Hyun Yang, Suwon-si (KR); Jaemok Jung, Suwon-si (KR)

(21) Appl. No.: 19/273,523

(22) Filed: Jul. 18, 2025

(30) Foreign Application Priority Data
Aug. 29, 2024 (KR) 10-2024-0116512

(51) Int. Cl. H01L 23/538; H01L 21/48; H01L 21/56; H01L 23/00; H01L 23/31; H01L 25/18; H10B 80/00; H10D 80/30

(52) U.S. Cl. CPC H01L 23/5385; H10B 80/00; H10D 80/30

(57) ABSTRACT

A semiconductor package includes a lower redistribution structure including a lower connection pad, a semiconductor chip on the lower redistribution structure, an upper redistribution structure on a back surface of the semiconductor chip and including a first connection region and a second connection region, a connecting member electrically connecting the lower connection pad and the first connection region, an encapsulant covering the semiconductor chip and surrounding a side surface of the upper redistribution structure, and an upper bonding pad on the upper redistribution structure and electrically connected to the second connection region. The second connection region is at a vertical level higher than a vertical level of the first connection region. The second connection region is coplanar with an upper surface of the encapsulant.

### CROSS-REFERENCE TO RELATED APPLICATION(S)

This application claims the benefit under 35 USC 119(a) of Korean Patent Application No. 10-2024-0116512, filed on Aug. 29, 2024 in the Korean Intellectual Property Office, the entire disclosure of which is incorporated herein by reference for all purposes.

### BACKGROUND

The present inventive concept relates to a semiconductor package including redistribution structures.

As the demand for high performance, high speed, and/or multifunctionality of semiconductor devices increases, the integration of semiconductor devices is increasing. In manufacturing semiconductor devices with fine patterns corresponding to the trend for high integration of semiconductor devices, implementing patterns having fine widths or fine gaps is required. Accordingly, the substrate on which semiconductor chips are mounted is continuously becoming thinner.

### SUMMARY

Example embodiments provide a semiconductor package including an upper redistribution structure disposed on a back surface of a semiconductor chip.

According to example embodiments, a semiconductor package includes a lower redistribution structure including a lower connection pad; a semiconductor chip on the lower redistribution structure; an upper redistribution structure on a back surface of the semiconductor chip and including a first connection region and a second connection region; a connecting member electrically connecting the lower connection pad and the first connection region; an encapsulant covering the semiconductor chip and surrounding a side surface of the upper redistribution structure; and an upper bonding pad on the upper redistribution structure and electrically connected to the second connection region. The second connection region is at a vertical level higher than a vertical level of the first connection region. The second connection region is coplanar with an upper surface of the encapsulant.

According to example embodiments, a semiconductor package includes a lower redistribution structure including a lower connection pad; a semiconductor chip on the lower redistribution structure; an upper redistribution structure on a back surface of the semiconductor chip; a connecting member electrically connecting the lower connection pad and the upper redistribution structure; an encapsulant on the semiconductor chip and surrounding a side surface of the upper redistribution structure; and an upper bonding pad on the upper redistribution structure and electrically connected to the upper redistribution structure. The upper redistribution structure includes: an upper connection pad electrically connected to the connecting member; a first upper insulating layer at least partially covering the upper connection pad; at least one second upper insulating layer on the first upper insulating layer; and a lower bonding pad within the at least one second upper insulating layer and in contact with the upper bonding pad. A lower surface of the lower bonding pad is at a higher vertical level than a lower surface of the upper connection pad.

According to example embodiments, a semiconductor package includes a lower redistribution structure including lower connection pads and chip connection pads; an external connection terminal below the lower redistribution structure; a semiconductor chip on the chip connection pads; an upper redistribution structure on a back surface of the semiconductor chip and including first connection regions and a second connection region; connecting members electrically connecting the lower connection pads and the first connection regions; an encapsulant on the semiconductor chip and covering a side surface of the upper redistribution structure; and an upper bonding pad on the upper redistribution structure and electrically connected to the second connection region. The second connection region is at a vertical level higher than a vertical level of the first connection regions. The second connection region is between the first connection regions when viewed from above. The second connection region is coplanar with an upper surface of the encapsulant.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor package according to example embodiments;

FIG. 2 is a vertical cross-sectional view taken along line I-I′ of the semiconductor package illustrated in FIG. 1;

FIG. 3 is an enlarged view of a portion of the semiconductor package illustrated in FIG. 2;

FIG. 4 is a vertical cross-sectional view of a semiconductor package according to example embodiments;

FIGS. 5A and 5B are flow charts illustrating a method of manufacturing a semiconductor package according to example embodiments;

FIGS. 6A to 6L are vertical cross-sectional views illustrating a method of manufacturing a semiconductor package according to example embodiments; and

FIG. 7 is a vertical cross-sectional view of a semiconductor package according to example embodiments.

### DETAILED DESCRIPTION

Hereinafter, example embodiments will be described with reference to the accompanying drawings.

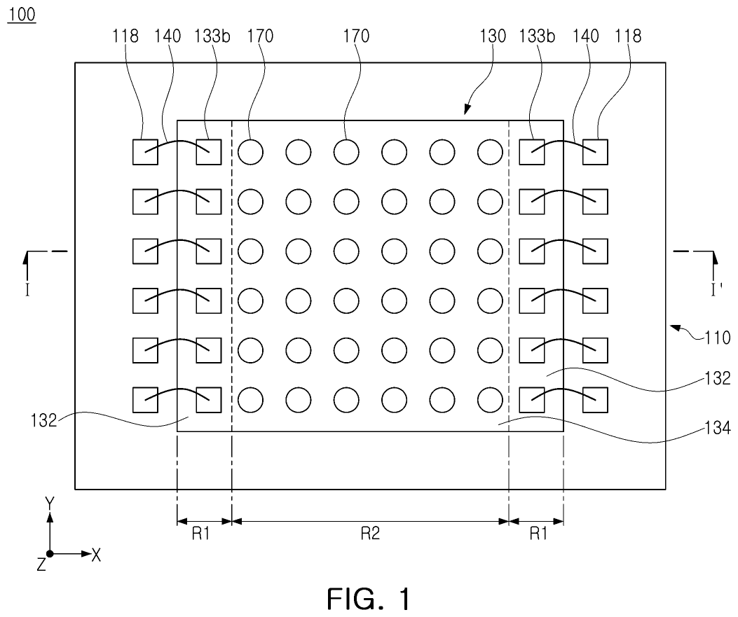

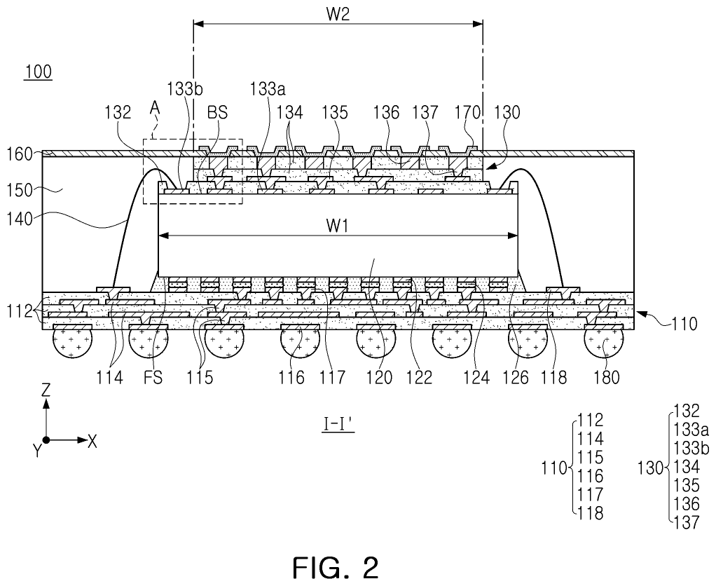

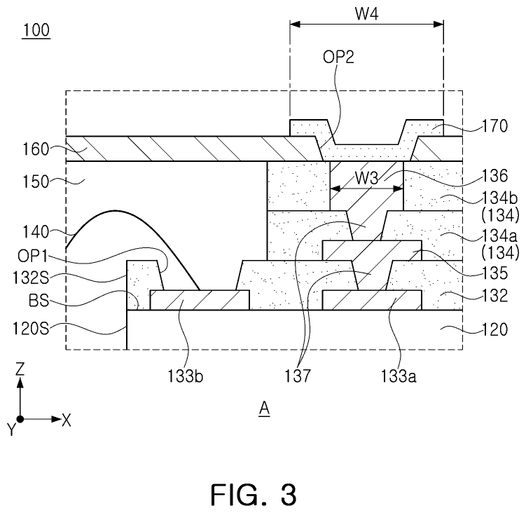

FIG. 1 is a plan view of a semiconductor package according to example embodiments. FIG. 2 is a vertical cross-sectional view taken along line I-I′ of the semiconductor package illustrated in FIG. 1. FIG. 3 is an enlarged view of a portion of the semiconductor package illustrated in FIG. 2.

Referring to FIGS. 1 to 3, a semiconductor package 100 according to example embodiments may include a lower redistribution structure 110, a semiconductor chip 120, an upper redistribution structure 130, a connecting member 140, an encapsulant 150, an upper protective layer 160, an upper bonding pad 170, and an external connection terminal 180.

The lower redistribution structure 110 may include a lower insulating layer 112, a lower redistribution layer 114, a lower via 115, a lower pad 116, a chip connection pad 117, and a lower connection pad 118. The lower redistribution structure 110 may be a support substrate on which the semiconductor chip 120 is mounted.

The lower insulating layer 112 may include an insulating resin. The insulating resin may include a thermosetting resin such as an epoxy resin, a thermoplastic resin such as a polyimide, or a resin impregnated with an inorganic filler or the like, for example, prepreg, Ajinomoto Build-up Film (ABF), or FR-4, Bismaleimide-Triazine (BT). For example, the lower insulating layer 112 may include a photosensitive resin such as Photo-Imageable Dielectric (PID). The lower insulating layer 112 may include a plurality of lower insulating layers 112. The lower insulating layers 112 may be stacked in a vertical direction (Z-axis direction). Depending on the process, the boundary between a plurality of lower insulating layers 112 may be unclear or undetectable.

The lower redistribution layers 114 may be disposed on or within the lower insulating layer 112 and may redistribute the chip pads 122 of the semiconductor chip 120. The lower redistribution layers 114 may include a metal including, for example, copper (Cu), aluminum (Al), silver (Ag), tin (Sn), gold (Au), nickel (Ni), lead (Pb), titanium (Ti), or alloys thereof. The lower redistribution layers 114 may perform various functions depending on the design. For example, the lower redistribution layers 114 may include a ground (GND) pattern, a power (PWR) pattern, and a signal (Signal: S) pattern. In this case, the signal (S) pattern may be defined as a transmission path of various signals, such as a data signal, excluding the ground (GND) pattern and the power (PWR) pattern. The lower redistribution layers 114 may include more or fewer redistribution layers than those illustrated in the drawing.

The lower vias 115 may extend vertically within the lower insulating layer 112 and be electrically connected to the lower redistribution layers 114. For example, the lower vias 115 may interconnect lower redistribution layers 114 at different vertical levels. The lower vias 115 may include signal vias, ground vias, and power vias. The lower vias 115 may include a metal material, such as copper (Cu), aluminum (Al), silver (Ag), tin (Sn), gold (Au), nickel (Ni), lead (Pb), titanium (Ti), or alloys thereof. The lower vias 115 may be filled vias in which a metal material is filled inside the via hole or conformal vias in which a metal material extends along the inner wall of the via hole.

The lower pad 116 may be disposed on the lower surface of the lower redistribution structure 110. For example, the lower pad 116 may be disposed on the lower surface of a lowermost lower insulating layer 112 among the lower insulating layers 112. The lower pad 116 may be electrically connected to at least one of the lower redistribution layers 114 through the lower via 115.

The chip connection pad 117 may be disposed on the upper surface of the lower redistribution structure 110. For example, the chip connection pad 117 may be disposed on the upper surface of an uppermost lower insulating layer 112 among the lower insulating layers 112. The chip connection pad 117 may be electrically connected to at least one of the lower redistribution layers 114 through the lower via 115. The chip connection pad 117 may be disposed on the center or center portion of the upper surface of the lower redistribution structure 110 and may electrically connect the semiconductor chip 120 to the lower redistribution structure 110.

The lower connection pad 118 may be disposed on the upper surface of the lower redistribution structure 110. For example, the lower connection pad 118 may be disposed on the upper surface of the uppermost lower insulating layer 112 among the lower insulating layers 112. The lower connection pad 118 may be electrically connected to at least one of the lower redistribution layers 114 through the lower via 115. The lower connection pad 118 may be disposed on the edge of the upper surface of the lower redistribution structure 110 and may electrically connect the upper redistribution structure 130 to the lower redistribution structure 110. In the plan view, the lower connection pad 118 is illustrated as having a quadrangular shape, but is not limited thereto. According to example embodiments, the lower connection pad 118 may have a circular or oval shape.

The lower pad 116, the chip connection pad 117, and the lower connection pad 118 may each include a metal including copper (Cu), aluminum (Al), silver (Ag), tin (Sn), gold (Au), nickel (Ni), lead (Pb), titanium (Ti), or alloys thereof. In example embodiments, the chip connection pad 117 and the lower connection pad 118 may be formed simultaneously and may include the same material. For example, the chip connection pad 117 and the lower connection pad 118 may respectively be formed by sequentially stacking metal layers including copper (Cu), nickel (Ni), and gold (Au).

The semiconductor chip 120 may include a chip pad 122 disposed on the lower redistribution structure 110 and electrically connected to the lower redistribution layers 114. The semiconductor chip 120 may be referred to as a lower semiconductor chip 120 or a first semiconductor chip 120. The semiconductor chip 120 may include a semiconductor wafer and a semiconductor wafer integrated circuit (IC) formed of a semiconductor element such as silicon or germanium, or a compound semiconductor such as silicon carbide (SiC), gallium arsenide (GaAs), indium arsenide (InAs), and indium phosphide (InP). The semiconductor chip 120 may be a bare semiconductor chip in which a separate bump or interconnection layer is not formed, but is not limited thereto, and may also be a packaged type semiconductor chip. The integrated circuit may be a logic circuit (or ‘logic chip’) such as a central processor (CPU), a graphics processor (GPU), a field programmable gate array (FPGA), an application processor (AP), a digital signal processor, a cryptographic processor, a microprocessor, a microcontroller, an analog-to-digital converter, an application-specific IC (ASIC) and the like, or a memory circuit (or ‘memory chip’) including a volatile memory such as a dynamic RAM (DRAM) and a static RAM (SRAM), and a non-volatile memory such as a phase change RAM (PRAM), a magnetic RAM (MRAM), a resistive RAM (RRAM), and a flash memory. In example embodiments, the semiconductor chip 120 may be a logic chip.

The semiconductor package 100 may further include connecting solders 124 and underfill 126 disposed between the lower redistribution structure 110 and the semiconductor chip 120. The connecting solders 124 may be disposed between the chip pad 122 and the chip connection pad 117, respectively, and may electrically connect the lower redistribution structure 110 and the semiconductor chip 120. The connecting solders 124 may include a low-melting-point metal. The low-melting-point metal may include, for example, tin (Sn), indium (In), bismuth (Bi), antimony (Sb), copper (Cu), silver (Ag), zinc (Zn), lead (Pb), or alloys thereof (for example, Sn-Ag-Cu).

The underfill 126 may be in or fill the space between the lower redistribution structure 110 and the semiconductor chip 120, and may cover the chip connection pad 117, the chip pad 122, and the connecting solders 124. The underfill 126 may surround side surfaces of the chip connection pad 117, the chip pad 122, and the connecting solders 124. The underfill 126 may include an insulating resin such as an epoxy resin, and may physically and electrically protect the chip connection pad 117, the chip pad 122, and the connecting solders 124. The underfill 126 may have a capillary underfill (CUF) structure, but is not limited thereto. According to example embodiments, the underfill 126 may also have a molded underfill (MUF) structure integrated with the encapsulant 150.

The upper redistribution structure 130 may be disposed on the semiconductor chip 120. For example, the semiconductor chip 120 may include a front surface (FS) and a back surface (BS). The front surface (FS) and the back surface (BS) may be referred to as an active surface and an inactive surface, respectively.

The semiconductor chip 120 may include a device layer. The device layer may include various microelectronic devices such as a micro-electro-mechanical system (MEMS), an active device, a passive device, and the like, a metal-oxide-semiconductor field effect transistor (MOSFET) such as a complementary metal-oxide-semiconductor transistor (CMOS transistor) or the like, a system large scale integration (LSI), a flash memory, a DRAM, an SRAM, an EEPROM, a PRAM, an MRAM, or a RERAM, and an image sensor such as a CMOS imaging sensor (CIS) or the like. One side of the semiconductor chip 120 on which the device layer is formed may be referred to as an active surface or the front surface (FS). For example, chip pads 122 may be disposed on the front surface (FS) of the semiconductor chip 120. The surface opposite to the active surface may be referred to as an inactive surface or the back surface (BS). In example embodiments, the upper redistribution structure 130 may be in contact with the back surface (BS) of the semiconductor chip 120 and may be disposed on the back surface (BS).

The upper redistribution structure 130 may include upper insulating layers 132 and 134, a first upper redistribution layer 133a, an upper connection pad 133b, a second upper redistribution layer 135, a lower bonding pad 136, and an upper via 137.

The upper insulating layers 132 and 134 may include a first upper insulating layer 132 and at least one second upper insulating layer 134 having different horizontal widths. For example, the first upper insulating layer 132 may be disposed at the lowermost portion of the upper insulating layers 132 and 134. The second upper insulating layer 134 may be disposed on the first upper insulating layer 132. In example embodiments, a plurality of second upper insulating layers 134 may be disposed on the first upper insulating layer 132.

In example embodiments, the upper redistribution structure 130 may have a first horizontal width W1 at a first vertical level and a second horizontal width W2 greater than the first horizontal width W1 at a second vertical level higher than the first vertical level. For example, the first upper insulating layer 132 may have a first horizontal width W1 and the second upper insulating layer 134 may have a second horizontal width W2. The first upper insulating layer 132 may include a first portion (e.g., a center portion) vertically overlapping the second upper insulating layer 134 and a second portion (e.g., an edge portion) not vertically overlapping the second upper insulating layer 134 and which is offset in the horizontal direction. In example embodiments, the horizontal width W1 of the first upper insulating layer 132 in the X-direction may be equal to the horizontal width of the semiconductor chip 120 in the X-direction. For example, the side surface 132S of the first upper insulating layer 132 may be coplanar with the side surface 120S of the semiconductor chip 120.

The upper insulating layers 132 and 134 may include an insulating resin. The insulating resin may include a thermosetting resin such as an epoxy resin, a thermoplastic resin such as a polyimide, or a resin impregnated with an inorganic filler, for example, prepreg, ABF, FR-4, BT, or PID. Depending on the process, the boundary between the upper insulating layers 132 and 134 may be unclear or undetectable.

The first upper redistribution layer 133a and the upper connection pad 133b may be disposed within the first upper insulating layer 132 and may be at least partially covered by the first upper insulating layer 132. For example, the first upper redistribution layer 133a and the upper connection pad 133b may be disposed at the same vertical level and may be disposed on the back surface (BS) of the semiconductor chip 120. The upper connection pads 133b may be disposed on the edge or edge portion of the back surface (BS) of the semiconductor chip 120, and the first upper redistribution layers 133a may be disposed on the center or center portion of the back surface (BS) of the semiconductor chip 120. For example, the upper connection pads 133b may be spaced apart from each other in the X-direction, and the first upper redistribution layers 133a may be disposed between the upper connection pads 133b. The upper connection pads 133b may not vertically overlap with the second upper insulating layers 134, and may be disposed to be offset in the horizontal direction from the second upper insulating layers 134. In the plan view, the upper connection pads 133b are illustrated as having a quadrangular shape, but are not limited thereto. According to example embodiments, the upper connection pad 133b may have a circular or oval shape.

The upper connection pad 133b may be electrically connected to a corresponding one of the first upper redistribution layers 133a. For example, the first upper redistribution layers 133a may extend in a horizontal direction, and at least one of the first upper redistribution layers 133a may be connected to the upper connection pad 133b. For example, when viewed in a plan view, the first upper redistribution layers 133a may each include a pad pattern and a line pattern connected to the pad pattern.

The upper surface of the first upper redistribution layer 133a may be partially or completely covered by the first upper insulating layer 132, and at least a portion of the upper surface of the upper connection pad 133b may be exposed by the first upper insulating layer 132. For example, the first upper insulating layer 132 may include an opening OP1 exposing the upper connection pad 133b. The upper surface of the upper connection pad 133b exposed by the opening OP1 may be connected to the connecting member 140.

The second upper redistribution layer 135 and the lower bonding pad 136 may be disposed within the second upper insulating layers 134 and may extend in a horizontal direction. For example, the second upper insulating layers 134 may include a second upper insulating layer 134a and a second upper insulating layer 134b on the second upper insulating layer 134a. The second upper redistribution layer 135 may be disposed on the first upper redistribution layer 133a and may be at least partially covered by the second upper insulating layer 134a. The second upper redistribution layers 135 may be electrically connected to corresponding ones of the first upper redistribution layers 133a, respectively.

The lower bonding pad 136 may be disposed within an uppermost second upper insulating layer 134b among the second upper insulating layers 134. For example, the lower bonding pad 136 may be disposed on the second upper redistribution layers 135, and the side surface of the lower bonding pad 136 may be covered or surrounded by the second upper insulating layer 134b. The upper surface of the lower bonding pad 136 may not be covered by the second upper insulating layer 134b and may be coplanar with the second upper insulating layer 134b or an upper surface thereof. In example embodiments, the second upper insulating layers 134a and 134b may have the same horizontal width in the X-direction, but is not limited thereto.

The first upper redistribution layer 133a, the upper connection pad 133b, the second upper redistribution layer 135, and the lower bonding pad 136 may include a metal material including copper (Cu), aluminum (Al), silver (Ag), tin (Sn), gold (Au), nickel (Ni), lead (Pb), titanium (Ti), or alloys thereof.

The upper vias 137 may extend vertically within the upper insulating layers 132 and 134 and be electrically connected to the first upper redistribution layer 133a, the upper connection pad 133b, the second upper redistribution layer 135, and the lower bonding pad 136. For example, the upper vias 137 may interconnect the first upper redistribution layer 133a and the second upper redistribution layer 135, and the second upper redistribution layer 135 and the lower bonding pad 136, which are disposed at different vertical levels. The upper vias 137 may include a metal material, for example, copper (Cu), aluminum (Al), silver (Ag), tin (Sn), gold (Au), nickel (Ni), lead (Pb), titanium (Ti), or alloys thereof. The upper vias 137 may be filled vias in which a metal material is filled inside a via hole or conformal vias in which a metal material extends along an inner wall of the via hole.

As illustrated in FIG. 1, when viewed in a plan view, the upper redistribution structure 130 may include first connection regions R1 and a second connection region R2. The first connection regions R1 may be disposed to be spaced apart from each other in the X-direction, and the second connection region R2 may be disposed between the first connection regions R1. The respective first connection regions R1 may include upper connection pads 133b disposed in the Y-direction. As illustrated in FIG. 2, the second connection region R2 may be disposed at a higher vertical level than the first connection regions R1. In this case, the first connection region R1 may be defined as or by the upper surface of the first upper insulating layer 132 and the upper surface of the upper connection pad 133b. The second connection region R2 may be defined as or by the upper surface of an uppermost second upper insulating layer 134b among the second upper insulating layers 134 and the upper surface of the lower bonding pad 136. The second connection region R2 may be coplanar with the upper surface of the encapsulant 150. The surface roughness of the second connection region R2 may be lower than the surface roughness of the upper surface of the encapsulant 150. Since the first connection regions R1 in which the upper connection pads 133b are disposed are disposed at a lower vertical level than the second connection region R2, a space for the connecting member 140, which may be a bonding wire, to be disposed may be secured, and thus the vertical length or height of the semiconductor package 100 may be reduced.

The connecting member 140 may electrically connect the lower redistribution structure 110 and the upper redistribution structure 130. For example, the connecting member 140 may be in contact with the upper surfaces of the lower connection pad 118 and the upper connection pad 133b, and may be connected to the lower connection pad 118 and the upper connection pad 133b. In example embodiments, the connecting member 140 may be a bonding wire. For example, the connecting member 140 may be a metal wire including at least one of copper (Cu) and gold (Au).

The encapsulant 150 may at least partially cover the lower redistribution structure 110 and the semiconductor chip 120. In example embodiments, the encapsulant 150 may cover or surround the side surface of the upper redistribution structure 130, and the upper surface of the encapsulant 150 may be coplanar with the upper surface of the upper redistribution structure 130. For example, the upper surface of the encapsulant 150 may be coplanar with the upper surfaces of the second upper insulating layer 134b and the lower bonding pad 136. In example embodiments, the surface roughness of the upper surfaces of the second upper insulating layer 134b and the lower bonding pad 136 may be lower than the surface roughness of the upper surface of the encapsulant 150. For example, the upper surfaces of the second upper insulating layer 134b and the lower bonding pad 136 may be flatter or smoother than the upper surface of the encapsulant 150.

The encapsulant 150 may cover the first connection regions R1 of the upper redistribution structure 130. For example, a portion of the encapsulant 150 may be vertically overlapped with the first upper insulating layer 132 and the upper connection pad 133b, and the encapsulant 150 may at least partially cover the first upper insulating layer 132 and the upper connection pad 133b.

The encapsulant 150 may be a resin including epoxy or polyimide. For example, the resin may include a bisphenol-group epoxy resin, a polycyclic aromatic epoxy resin, an o-Cresol Novolac epoxy resin, a biphenyl-group epoxy resin, or a naphthalene-group epoxy resin. The encapsulant 150 may further include an inorganic filler, and the inorganic filler may include, for example, silica.

The upper protective layer 160 may cover the upper surface of the encapsulant 150 and at least a portion of the upper surface of the upper redistribution structure 130. For example, the upper protective layer 160 may cover at least a portion of the upper surface of the second upper insulating layer 134b. The upper protective layer 160 may include an opening OP2 that exposes the lower bonding pad 136.

The upper protective layer 160 may include an insulating resin. The insulating resin may include a thermosetting resin such as an epoxy resin, a thermoplastic resin such as a polyimide, or a resin impregnated with an inorganic filler, such as prepreg, ABF, FR-4, BT, or PID.

The upper bonding pad 170 may be disposed on the opening OP2 of the upper protective layer 160. For example, the upper bonding pad 170 may be in contact with the upper protective layer 160 and the lower bonding pad 136. The upper bonding pad 170 may be electrically connected to the lower redistribution structure 110 through the upper redistribution structure 130 and the connecting member 140. The maximum horizontal width W4 of the upper bonding pad 170 may be greater than the horizontal width W3 of the lower bonding pad 136.

The upper bonding pad 170 may include a metal material including copper (Cu), aluminum (Al), silver (Ag), tin (Sn), gold (Au), nickel (Ni), lead (Pb), titanium (Ti), or alloys thereof. For example, the upper bonding pad 170 may be formed by sequentially stacking metal layers including nickel (Ni) and gold (Au), respectively.

The external connection terminal 180 may be disposed below the lower redistribution structure 110. For example, the external connection terminal 180 may be in contact with the lower pad 116. The external connection terminal 180 may include a conductive material and may have a ball, pin, or lead shape. For example, the external connection terminal 180 may be a solder ball.

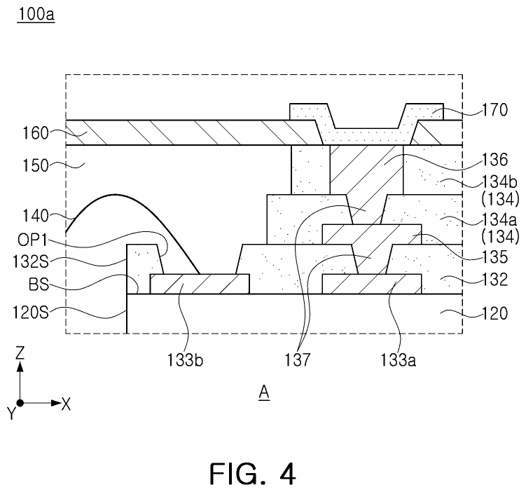

FIG. 4 is a vertical cross-sectional view of a semiconductor package according to example embodiments.

Referring to FIG. 4, a semiconductor package 100a may include an upper redistribution structure 130 disposed on a semiconductor chip 120. In example embodiments, the second upper insulating layers 134 of the upper redistribution structure 130 may have different horizontal widths, and the side surfaces of the second upper insulating layers 134 may not be coplanar. For example, the second upper insulating layers 134 may include a second upper insulating layer 134a and a second upper insulating layer 134b on the second upper insulating layer 134a, and the horizontal width of the second upper insulating layer 134a may be greater than the horizontal width of the second upper insulating layer 134b.

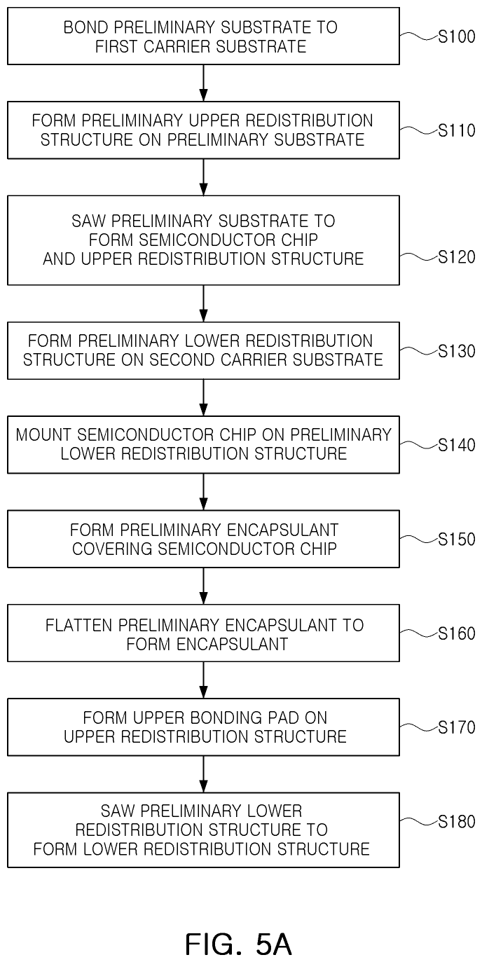

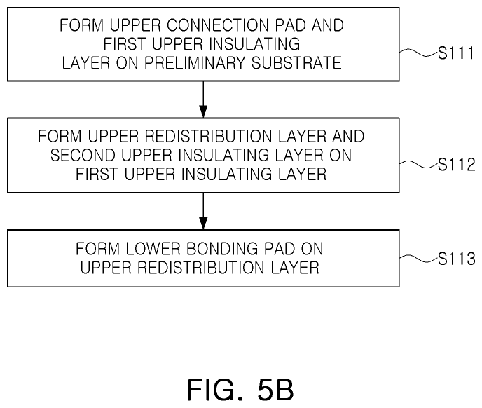

FIG. 5A and FIG. 5B are flow charts illustrating a method of manufacturing a semiconductor package according to example embodiments.

Referring to FIG. 5A, a semiconductor package manufacturing method according to example embodiments may include bonding a preliminary substrate to a first carrier substrate (S100), forming a preliminary upper redistribution structure on the preliminary substrate (S110), sawing the preliminary substrate to form a semiconductor chip and an upper redistribution structure (S120), forming a preliminary lower redistribution structure on a second carrier substrate (S130), mounting a semiconductor chip on the preliminary lower redistribution structure (S140), forming a preliminary encapsulant covering the semiconductor chip (S150), flattening the preliminary encapsulant to form an encapsulant (S160), forming an upper bonding pad on the upper redistribution structure (S170), and sawing the preliminary lower redistribution structure to form a lower redistribution structure (S180).

Referring to FIG. 5B, forming a preliminary upper redistribution structure on a preliminary substrate (S110) may include forming an upper connection pad and a first upper insulating layer on the preliminary substrate (S111), forming an upper redistribution layer and a second upper insulating layer on the first upper insulating layer (S112), and forming a lower bonding pad on the upper redistribution layer (S113).

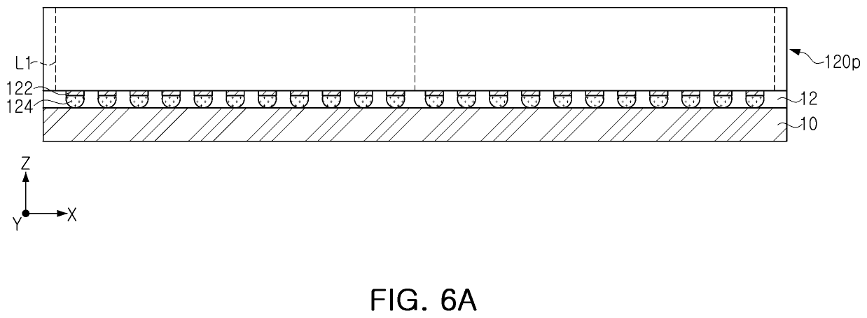

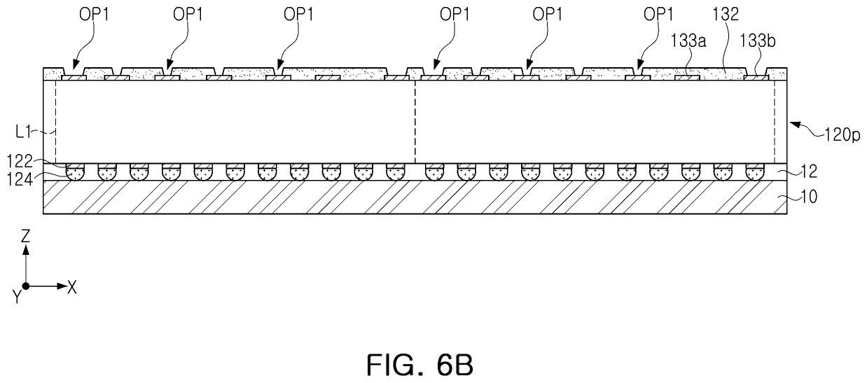

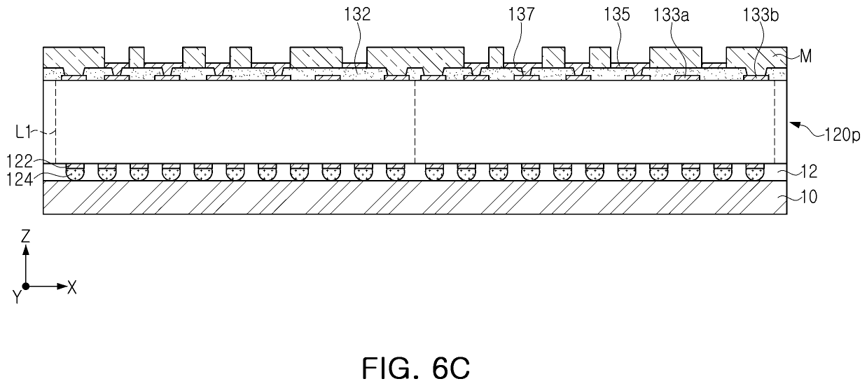

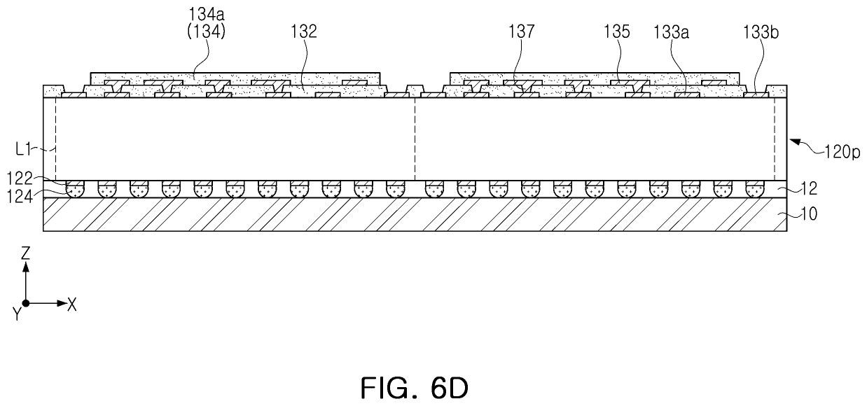

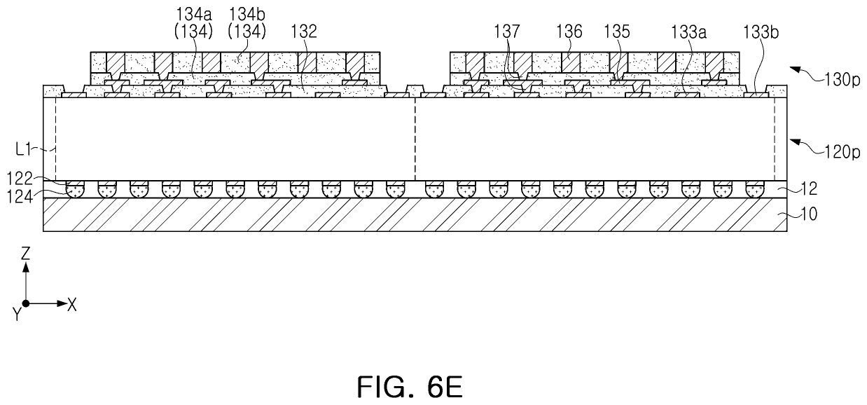

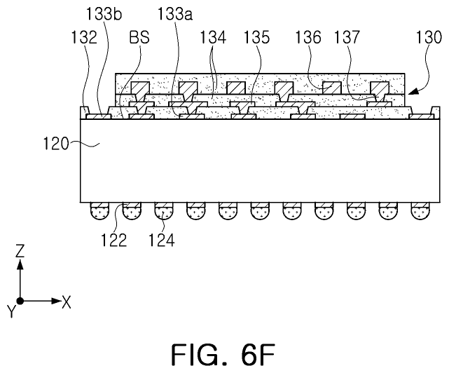

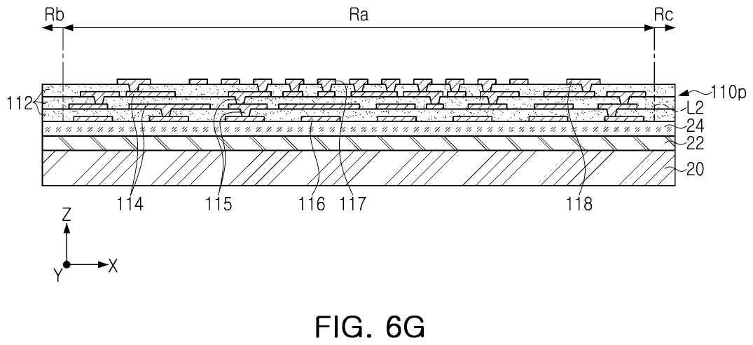

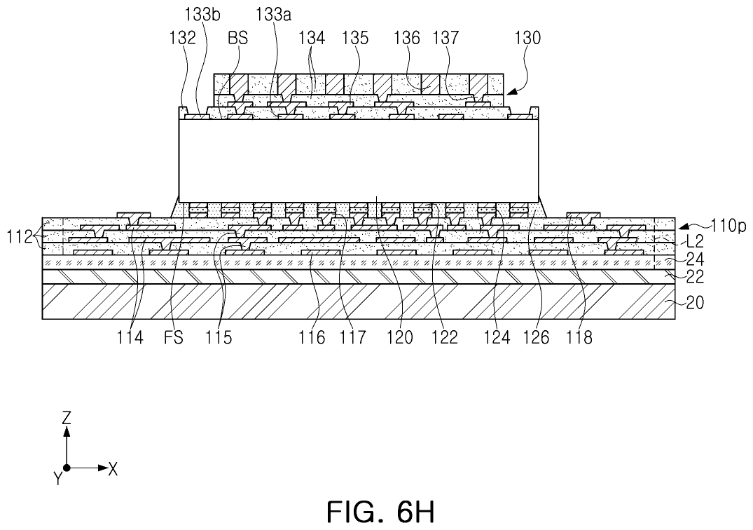

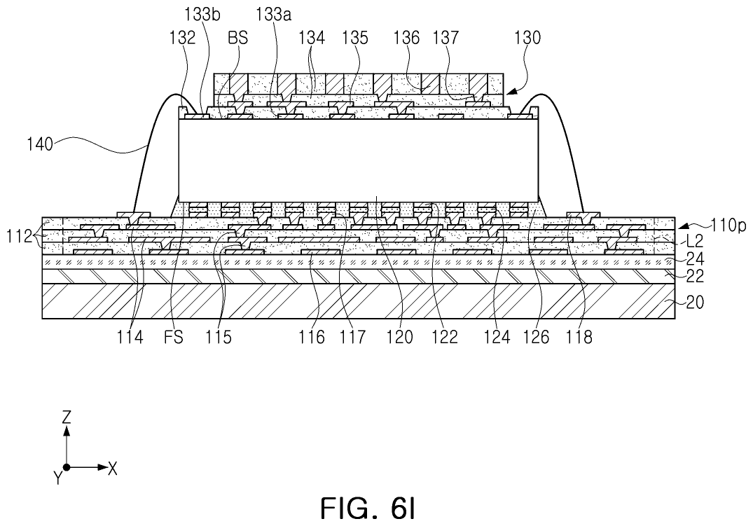

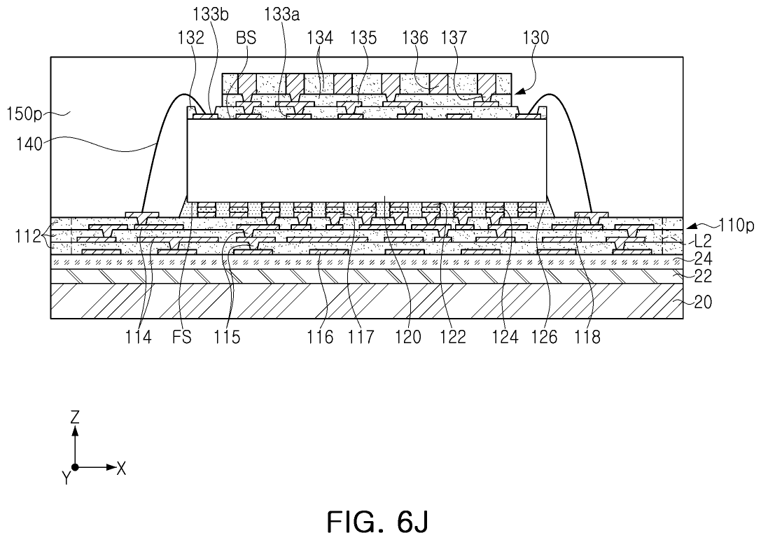

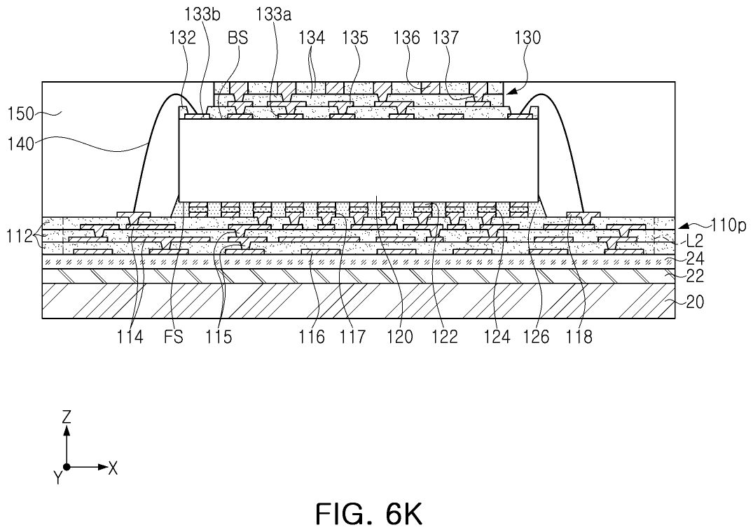

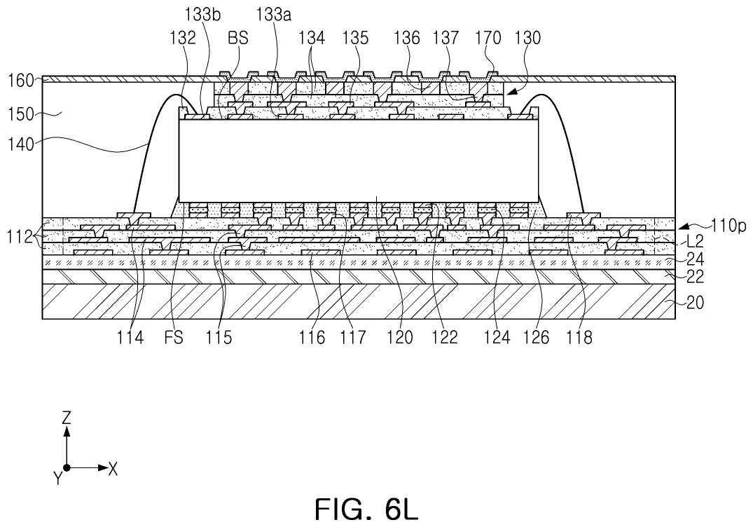

FIGS. 6A to 6L are vertical cross-sectional views illustrating a semiconductor package manufacturing method according to example embodiments.

Referring to FIGS. 5A and 6A, a preliminary substrate 120p may be bonded to a first carrier substrate 10 (S100). For example, the preliminary substrate 120p may be bonded to the first carrier substrate 10 by an adhesive layer 12. The adhesive layer 12 may cover or surround chip pads 122 and connecting solders 124 of the preliminary substrate 120p.

Referring to FIGS. 5B and 6B, an upper connection pad 133b and a first upper insulating layer 132 may be formed on a preliminary substrate 120p (S111). A first upper redistribution layer 133a may be further formed at the same vertical level as the upper connection pad 133b. The first upper redistribution layer 133a and the upper connection pad 133b may be formed by forming a seed layer on the preliminary substrate 120p and performing a plating process using the seed layer as a seed.

The first upper insulating layer 132 may be formed to cover the first upper redistribution layer 133a and the upper connection pad 133b. The first upper insulating layer 132 may be patterned to form openings OP1. At least one of the first upper redistribution layers 133a may be exposed by the openings OP1, and the upper connection pad 133b may be exposed by the openings OP1.

Referring to FIGS. 5B, 6C, and 6D, a second upper redistribution layer 135 and a second upper insulating layer 134a may be formed on the first upper insulating layer 132 (S112). First, referring to FIG. 6C, a mask layer M may be formed on the first upper insulating layer 132. The mask layer M may be patterned to expose at least one of the first upper redistribution layers 133a. The upper connection pad 133b may be covered by the mask layer M.

An upper via 137 and a second upper redistribution layer 135 may be formed on the first upper redistribution layers 133a exposed by the mask layer M. For example, the upper via 137 and the second upper redistribution layer 135 may be formed by performing a plating process.

Referring to FIG. 6D, the mask layer M may be removed, and a second upper insulating layer 134a may be formed on the first upper insulating layer 132. The second upper insulating layer 134a may be formed by forming an insulating material layer to cover the second upper redistribution layer 135, and then patterning the insulating material layer so that the upper connection pads 133b are exposed.

Referring to FIGS. 5B and 6E, a lower bonding pad 136 may be formed on a second upper redistribution layer 135 (S113), and a preliminary upper redistribution structure 130p may be manufactured. For example, a plating process may be performed on the second upper redistribution layer 135 illustrated in FIG. 6D to form an upper via 137 and a lower bonding pad 136. After forming an insulating material layer to cover a side surface of the lower bonding pad 136, the insulating material layer may be patterned to expose the upper connection pads 133b, and a second upper insulating layer 134b may be formed.

Referring to FIGS. 5A and 6F, a semiconductor chip 120 and an upper redistribution structure 130 may be formed by sawing a preliminary substrate 120p (S120). For example, a sawing process may be performed along cutting lines L1, and the preliminary substrate 120p and the preliminary upper redistribution structure 130p may be sawed to form the semiconductor chip 120 and the upper redistribution structure 130, respectively. Since the preliminary substrate 120p and the preliminary upper redistribution structure 130p are sawed simultaneously, the semiconductor chip 120 and the upper redistribution structure 130 may have horizontal widths of the same size. The first carrier substrate 10 and the adhesive layer 12 may be removed. A process of testing each semiconductor chip 120 and the upper redistribution structure 130 on each semiconductor chip 120 to determine a known good die (KGD) may be performed.

Referring to FIGS. 5A and 6G, a preliminary lower redistribution structure 110p may be formed on a second carrier substrate 20 (S130). For example, a release layer 22 and a metal layer 24 may be sequentially stacked and disposed on the second carrier substrate 20, and the preliminary lower redistribution structure 110p may be formed on the metal layer 24. The release layer 22 may include a light-to-heat-conversion (LTHC) material and may be coated on the second carrier substrate 20. In example embodiments, the LTHC coating may be decomposed by energy light such as a laser, thereby separating a structure bonded thereon from the second carrier substrate 20. The metal layer 24 may include a metal such as copper (Cu). The metal layer 24 may protect the release layer 22.

The preliminary lower redistribution structure 110p may include a lower insulating layer 112, a lower redistribution layer 114, a lower via 115, a lower pad 116, a chip connection pad 117, and a lower connection pad 118. The preliminary lower redistribution structure 110p may be manufactured by repeating a process of forming metal material layers by a plating process and forming an insulating layer covering the metal material layers.

After the preliminary lower redistribution structure 110p is manufactured, a process of testing respective regions Ra, Rb and Rc of the preliminary lower redistribution structure 110p to determine a normal region may be performed. Respective regions Ra, Rb and Rc may correspond to the lower redistribution structure 110 of the semiconductor package 100 illustrated in FIG. 2.

Referring to FIGS. 5A and 6H, a semiconductor chip 120 may be mounted on the preliminary lower redistribution structure 110p (S140). For example, the semiconductor chip 120 may be mounted on a region determined as a normal region among regions Ra, Rb and Rc. A semiconductor chip 120 may not be mounted on a region that is not determined as a normal region among regions Ra, Rb and Rc, or a dummy chip may be mounted.

The semiconductor chip 120 may be mounted on the preliminary lower redistribution structure 110p by a flip chip bonding method. For example, connecting solders 124 may be disposed on chip connection pads 117, and an underfill 126 may be formed between the semiconductor chip 120 and the preliminary lower redistribution structure 110p.

Referring to FIG. 61, a connecting member 140 may be formed. The connecting member 140 may connect the lower connection pad 118 of the preliminary lower redistribution structure 110p and the upper connection pad 133b of the upper redistribution structure 130. The connecting member 140 may be a bonding wire and may electrically connect the preliminary lower redistribution structure 110p and the upper redistribution structure 130.

Referring to FIGS. 5A and 6J, a preliminary encapsulant 150p covering the semiconductor chip 120 may be formed (S150). The preliminary encapsulant 150p may completely cover the upper surface of the upper redistribution structure 130.

Referring to FIGS. 5A and 6K, the preliminary encapsulant 150p may be flattened to form the encapsulant 150 (S160). The upper portion of the preliminary encapsulant 150p and the upper portion of the upper redistribution structure 130 may be removed by the flattening process. For example, the second upper insulating layer 134b and the lower bonding pad 136 may be partially etched. After the flattening process, upper surfaces of the second upper insulating layer 134b and the lower bonding pad 136 may be coplanar with the upper surface of the encapsulant 150.

Referring to FIGS. 5A and 6L, the upper bonding pad 170 may be formed on the upper redistribution structure 130 (S170). First, the upper protective layer 160 may be formed on the encapsulant 150. For example, an insulating material layer may be formed on an encapsulant 150, the insulating material layer may be patterned to expose the lower bonding pad 136, and the insulating material layer may be cured to form an upper protective layer 160. An upper bonding pad 170 may be formed on the lower bonding pad 136 exposed by the upper protective layer 160.

Referring to FIG. 5A and FIG. 2, a semiconductor package 100 may be manufactured by sawing the preliminary lower redistribution structure 110p to form a lower redistribution structure 110 (S180), and forming an external connection terminal 180.

For example, a lower redistribution structure 110 may be formed by sawing a preliminary lower redistribution structure 110p along cutting lines L2. The second carrier substrate 20, the release layer 22, and the metal layer 24 may be removed, and an external connection terminal 180 may be formed on the lower pad 116 of the lower redistribution structure 110.

As illustrated in FIGS. 6A to 6L, since the semiconductor chip 120 and the upper redistribution structure 130 are formed in a separate process from the lower redistribution structure 110, the process of determining the KGD and the process of determining the normal region of the preliminary lower redistribution structure 110p may be performed separately. Accordingly, the defect rate of the semiconductor package 100 may be reduced, and the yield may be improved. In addition, since the lower redistribution structure 110 and the upper redistribution structure 130 are not formed in a series of processes on one wafer, but are formed in separate processes, the semiconductor chip 120 and the upper redistribution structure 130 may be manufactured in advance before forming the preliminary lower redistribution structure 110p. Therefore, the productivity of the semiconductor package manufacturing process may be improved.

As illustrated in FIG. 6K, a process (S160) of flattening the preliminary encapsulant 150p may be performed in the semiconductor package manufacturing process. The preliminary encapsulant 150p may include a material such as silica as an inorganic filler, and if the upper surface of the encapsulant 150 is not locally flattened, there is a concern that a defect may occur in the interconnection structure formed on the encapsulant 150 due to undulation. However, according to the example embodiments, when the preliminary encapsulant 150p is flattened, the second upper insulating layer 134 and the lower bonding pad 136 of the upper redistribution structure 130 may be flattened. The second upper insulating layer 134 and the lower bonding pad 136 may have a lower surface roughness than the upper surface of the encapsulant 150, and the upper surfaces of the second upper insulating layer 134 and the lower bonding pad 136 may be relatively flat. Therefore, when the upper bonding pad 170 is formed on the lower bonding pad 136, the defect of the semiconductor package 100 may be reduced compared to forming the interconnection structure on the upper surface of the encapsulant 150.

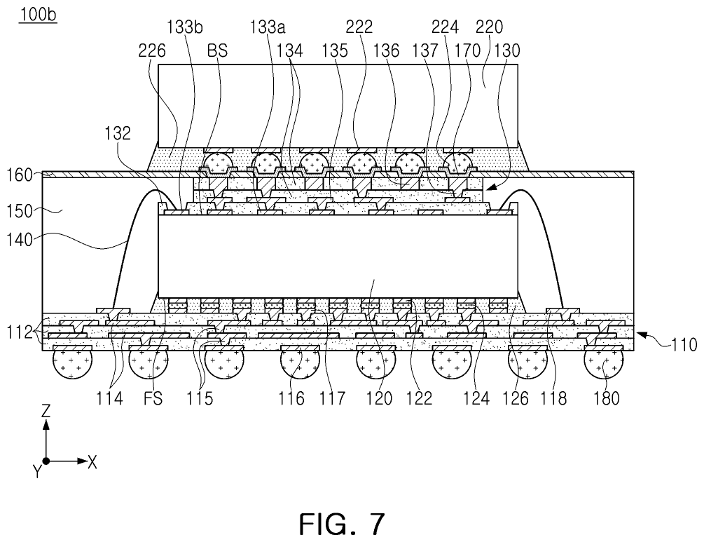

FIG. 7 is a vertical cross-sectional view of a semiconductor package according to example embodiments.

Referring to FIG. 7, a semiconductor package 100b may further include a semiconductor chip 220 mounted on the upper bonding pad 170. The semiconductor chip 220 may be mounted in a flip chip manner. For example, the semiconductor chip 220 may include chip pads 222 on the lower surface, and the chip pads 222 and upper bonding pads 170 may be electrically connected by connecting solders 224. An underfill 226 may be disposed between the semiconductor chip 220 and the upper protective layer 160. In example embodiments, the semiconductor chip 120 may be a logic chip, and the semiconductor chip 220 may be a memory chip.

As set forth above, according to example embodiments, since an upper bonding pad is formed on an upper surface of an upper redistribution structure rather than an upper surface of an encapsulant, occurrence of undulation may be prevented. Since a lower redistribution structure and the upper redistribution structure may be respectively formed separately rather than in a series of processes, productivity of a semiconductor package manufacturing process may be improved.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a lower redistribution structure including a lower connection pad;
a semiconductor chip on the lower redistribution structure;
an upper redistribution structure on a back surface of the semiconductor chip and including a first connection region and a second connection region;
a connecting member electrically connecting the lower connection pad and the first connection region;
an encapsulant covering the semiconductor chip and surrounding a side surface of the upper redistribution structure; and
an upper bonding pad on the upper redistribution structure and electrically connected to the second connection region,
wherein the second connection region is at a vertical level higher than a vertical level of the first connection region, and
the second connection region is coplanar with an upper surface of the encapsulant.

2. The semiconductor package of claim 1, wherein the upper redistribution structure further includes an upper connection pad in the first connection region,
wherein the upper connection pad is in contact with the connecting member and electrically connected to the lower connection pad.

3. The semiconductor package of claim 2, wherein an upper surface of the upper connection pad is in contact with the encapsulant.

4. The semiconductor package of claim 2, wherein the upper redistribution structure further includes a first upper insulating layer in contact with the back surface of the semiconductor chip and partially covering the upper connection pad,
wherein a side surface of the first upper insulating layer is coplanar with a side surface of the semiconductor chip.

5. The semiconductor package of claim 4, wherein a horizontal width of the first upper insulating layer is the same as a horizontal width of the semiconductor chip.

6. The semiconductor package of claim 1, wherein the upper redistribution structure further includes a lower bonding pad in the second connection region,
wherein an upper surface of the lower bonding pad is in contact with the upper bonding pad.

7. The semiconductor package of claim 6, wherein a maximum horizontal width of the upper bonding pad is larger than a horizontal width of the lower bonding pad.

8. The semiconductor package of claim 6, wherein the lower bonding pad is coplanar with the upper surface of the encapsulant.

9. The semiconductor package of claim 6, wherein the upper redistribution structure further includes a second upper insulating layer surrounding a side surface of the lower bonding pad,
wherein the second upper insulating layer is coplanar with the upper surface of the encapsulant.

10. The semiconductor package of claim 9, wherein a horizontal width of the second upper insulating layer is smaller than a horizontal width of the semiconductor chip.

11. The semiconductor package of claim 1, wherein the connecting member includes a bonding wire.

12. The semiconductor package of claim 1, wherein the semiconductor chip includes chip pads on a front surface opposite to the back surface,
wherein the chip pads are electrically connected to the lower redistribution structure.

13. The semiconductor package of claim 1, wherein a surface roughness of the second connection region is lower than a surface roughness of the upper surface of the encapsulant.

14. A semiconductor package comprising:
a lower redistribution structure including a lower connection pad;
a semiconductor chip on the lower redistribution structure;
an upper redistribution structure on a back surface of the semiconductor chip;
a connecting member electrically connecting the lower connection pad and the upper redistribution structure;
an encapsulant on the semiconductor chip and surrounding a side surface of the upper redistribution structure; and
an upper bonding pad on the upper redistribution structure and electrically connected to the upper redistribution structure,
wherein the upper redistribution structure includes:
an upper connection pad electrically connected to the connecting member;
a first upper insulating layer at least partially covering the upper connection pad;
at least one second upper insulating layer on the first upper insulating layer; and
a lower bonding pad within the at least one second upper insulating layer and in contact with the upper bonding pad,
wherein a lower surface of the lower bonding pad is at a higher vertical level than a lower surface of the upper connection pad.

15. The semiconductor package of claim 14, wherein a side surface of the lower bonding pad is surrounded by an uppermost second upper insulating layer among the at least one second upper insulating layer.

16. The semiconductor package of claim 15, wherein an upper surface of the lower bonding pad and an upper surface of the uppermost second upper insulating layer among the at least one second upper insulating layer are coplanar with an upper surface of the encapsulant.

17. The semiconductor package of claim 14, wherein the at least one second upper insulating layer includes a plurality of second upper insulating layers at least some of which having different horizontal widths.

18. The semiconductor package of claim 14, wherein a horizontal width of the first upper insulating layer is greater than a horizontal width of the at least one second upper insulating layer.

19. The semiconductor package of claim 14, further comprising an upper protective layer covering an upper surface of the encapsulant,
wherein the upper protective layer includes an opening exposing the lower bonding pad, and
the upper bonding pad is in or on the opening.

20. A semiconductor package comprising:
a lower redistribution structure including lower connection pads and chip connection pads;
an external connection terminal below the lower redistribution structure;
a semiconductor chip on the chip connection pads;
an upper redistribution structure on a back surface of the semiconductor chip and including first connection regions and a second connection region;
connecting members electrically connecting the lower connection pads and the first connection regions;
an encapsulant on the semiconductor chip and covering a side surface of the upper redistribution structure; and
an upper bonding pad on the upper redistribution structure and electrically connected to the second connection region,
wherein the second connection region is at a vertical level higher than a vertical level of the first connection regions,
the second connection region is between the first connection regions when viewed from above, and
the second connection region is coplanar with an upper surface of the encapsulant.
